(19) United States
(12) Patent Application Publication
(10) Pub. No.: US 2022/0254633 A1
(43) Pub. Date: Aug. 11, 2022

(54) Semiconductor Layered Structure

(71) Applicant: Nippon Telegraph and Telephone Corporation, Tokyo (JP)

(72) Inventors: Ryo Nakao, Tokyo (JP); Tomonari Sato, Tokyo (JP)

(21) Appl. No.: 17/609,477

(22) PCT Filed: May 16, 2019
(86) PCT No.: PCT/JP2019/019489

§ 371 Date: Nov. 8, 2021

(51) Int. Cl. H01L 21/02

(52) U.S. Cl. CPC H01L 21/02565; H01L 21/02463; H01L 21/02381; H01L 21/02164; H01L 21/02461

(57) ABSTRACT

A semiconductor laminated structure includes a first buffer layer formed on a substrate, an insulating layer formed on the first buffer layer, a second buffer layer, an oxide layer formed on the second buffer layer, and a semiconductor layer formed on the oxide layer. The second buffer layer is formed by being regrown through an opening portion from a surface of the substrate which is exposed through the opening portion. A total thickness of the second buffer layer and the oxide layer is larger than a value obtained by multiplying a width of the opening portion by the square root of two (\sqrt{2}).

This patent application is a national phase filing under section 371 of PCT/JP2019/019489, filed May 16, 2019, which application is hereby incorporated herein by reference in its entirety.

### TECHNICAL FIELD

The present invention relates to a semiconductor laminated structure including a semiconductor layer constituting an optical device.

### BACKGROUND

A semiconductor is used as a material of an electronic device or an optical device. Most semiconductors used as devices have a layered structure and are formed on a substrate such as a semiconductor or sapphire serving as a base material by using a crystal growth device.

Originally, crystal growth was performed with lattice matching with a substrate. However, in order to improve mass productivity and device characteristics, growth of a lattice mismatch system (heteroepitaxial growth) such as growth of GaN on a sapphire substrate and growth of a compound semiconductor on a Si substrate has also been performed.

In heteroepitaxial growth, various crystal defects are introduced at a hetero interface, and these defects penetrate a layer (device layer) constituting a semiconductor electronic and optical device. Since these penetrating defects deteriorate device characteristics, it is important to suppress the penetrating defects in order not to deteriorate device characteristics.

Some techniques for reducing a threading dislocation density have been proposed so far, and one of these techniques is epitaxial lateral overgrowth (ELO). In addition, examples of a technique for reducing a threading dislocation density include aspect ratio trapping (ART), confined epitaxial lateral overgrowth (CELO), and the like. In addition, examples of a technique for reducing a threading dislocation density include a dislocation filter based on a strained layer superlattice (SLS), and the like.

For example, in ELO, a mask material such as SiO₂ is deposited on a semiconductor substrate to be heteroepitaxially grown to form a mask layer, an opening portion is formed in a portion of the mask layer, and crystal growth is performed from the opening portion (see NPL 1). In the crystal growth from the opening portion, the propagation of a dislocation from the substrate can be suppressed on the mask layer by using a growth mode in which crystal is grown to cover the mask layer in addition to a portion directly above the opening portion of the mask layer. However, lateral crystal growth on a mask is more difficult than general substrate vertical growth, and the shape and pattern of a mask are limited, which results in a problem that a required semiconductor device structure cannot necessarily be manufactured.

ART is a method of terminating a dislocation at an opening inner wall by forming a stripe structure in which a ratio of the thickness of an insulating layer to a mask opening (aspect ratio) is increased and selectively growing a semiconductor layer (device layer) in the opening portion (see NPL 2). However, regarding a dislocation occurring at a hetero interface, there is a possibility that a dislocation will be introduced into a device layer due to the movement of the dislocation in association with an operation in the actual use of a manufactured device, which results in a problem of lack of reliability.

CELO is a method of significantly reducing a dislocation density by forming a thin channel on the surface of a substrate by processing an insulating film or the like and supplying raw materials through the channel to grow a semiconductor layer (see NPL 3). However, in this method, the manufacture of a channel structure becomes complicated, and a region in which the semiconductor layer can be grown is extremely reduced. In addition, the semiconductor layer is also required to be grown on a crystal surface in a direction other than the vertical direction of the substrate, and thus it becomes difficult to perform growth itself.

A dislocation filter based on a strained layer superlattice (SLS) has been more widely used than before because of the ease of manufacture thereof (see NPL 4). However, in this technique, an effect of reducing a dislocation is small, and an insulating layer is not included. Accordingly, it is not possible to necessarily prevent a dislocation from operating and being inserted into the side of a device layer after a device structure is manufactured.

### CITATION LIST

### Non Patent Literature

[NPL 1] H. Kataria et al., “Simple Epitaxial Lateral Overgrowth Process as a Strategy for Photonic Integration on Silicon”, IEEE Journal of Selected Topics in Quantum Electronics, vol. 20, no. 4, 8201407, 2014.
[NPL 2] J. G. Fiorenza et al., “Aspect Ratio Trapping: a Unique Technology for Integrating Ge and III-Vs with Silicon CMOS”, ECS Transactions, vol. 33, no. 6, pp. 963-976, 2010.
[NPL 3] L. Czornomaz et al., “Confined Epitaxial Lateral Overgrowth (CELO): A Novel Concept for Scalable Integration of CMOS-compatible InGaAs-on-insulator MOSFETs on Large-Area Si Substrates”, Symposium on VLSI Technology Digest of Technical Papers, 13-3, pp. T172-T173, 2015.
[NPL 4] R. Hull et al., “Role of strained layer superlattices in misfit dislocation reduction in growth of epitaxial Ge0.5Si0.5 alloys on Si (100) substrates”, Journal of Applied Physics, vol. 65, no. 12, pp. 4723-4729, 1989.
[NPL 5] Y. Hirai et al., “Characterization of the Oxide Film Obtained by Wet Oxidation of Al-Rich AlGaAs”, Japanese Journal of Applied Physics, vol. 51, 02BG10, 2012.

### SUMMARY

### Technical Problem

As described above, in the conventional art, various methods of reducing a dislocation density at the time of performing heteroepitaxial growth have been proposed, but a technique for simply achieving a significant reduction in a dislocation density and having an effect of suppressing ascending movement of dislocation after manufacture has not been proposed.

Embodiments of the present invention can solve the above-described problems, and an object thereof is to simply manufacture a semiconductor layer with a significantly reduced dislocation density to suppress ascending movement of dislocation after the manufacture.

### Means for Solving the Problem

A semiconductor laminated structure according to embodiments of the present invention includes a first buffer layer which is formed on a substrate and formed of a first semiconductor having a different lattice constant in a plane direction from the substrate, an insulating layer which includes an opening portion and is formed on the first buffer layer, a second buffer layer which is formed of the first semiconductor and formed through the opening portion from a surface of the substrate which is exposed through the opening portion, an oxide layer which is formed on the second buffer layer and formed of an oxide of a semiconductor, and a semiconductor layer which is formed on the oxide layer and formed of a second semiconductor, in which a total thickness of the second buffer layer and the oxide layer is larger than a value obtained by multiplying a width of the opening portion by the square root of two (\sqrt{2}).

In one configuration example of the semiconductor laminated structure, the oxide layer may be formed of an oxide of a semiconductor on which crystal growth of the semiconductor layer is able to be performed.

In one configuration example of the semiconductor laminated structure, the substrate may be formed of Si.

In one configuration example of the semiconductor laminated structure, the first buffer layer and the second buffer layer may be formed of GaAs or InP.

In one configuration example of the semiconductor laminated structure, the oxide layer may be formed of AlAs, AlGaAs, AlAsSb, or an oxide of a compound semiconductor thereof.

### Effects of Embodiments of the Invention

As described above, according to embodiments of the present invention, a total thickness of a second buffer layer and an oxide layer formed from an opening portion of an insulating layer is made larger than a value obtained by multiplying the width of the opening portion by \sqrt{2}, and thus it is possible to simply manufacture a semiconductor layer with a significantly reduced dislocation density and to suppress ascending movement of dislocation after the manufacture.

### BRIEF DESCRIPTION OF THE DRAWINGS

FIG. 1 is a cross-sectional view illustrating a configuration of a semiconductor laminated structure according to an embodiment of the present invention.

FIG. 2A is a cross-sectional view illustrating a state during the manufacture of the semiconductor laminated structure according to an embodiment of the present invention.

FIG. 2B is a cross-sectional view illustrating a state during the manufacture of the semiconductor laminated structure according to an embodiment of the present invention.

FIG. 2C is a cross-sectional view illustrating a state during the manufacture of the semiconductor laminated structure according to an embodiment of the present invention.

FIG. 3 is a characteristic diagram illustrating a relationship between a width of an opening portion and a total thickness of a second buffer layer and an oxide layer.

### DETAILED DESCRIPTION OF ILLUSTRATIVE EMBODIMENTS

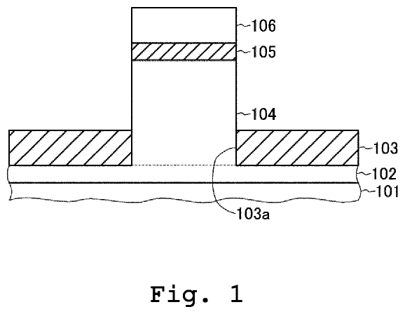

Hereinafter, a semiconductor laminated structure according to an embodiment of the present invention will be described with reference to FIG. 1. The semiconductor laminated structure includes a first buffer layer 102 formed on a substrate 101, an insulating layer 103 formed on the first buffer layer 102, a second buffer layer 104, an oxide layer 105 formed on the second buffer layer 104, and a semiconductor layer 106 formed on the oxide layer 105.

The substrate 101 is formed of, for example, Si. The substrate 101 can be formed of, for example, sapphire (Al₂O₃). The first buffer layer 102 is formed of a semiconductor (first semiconductor) having a different lattice constant in a plane direction from the substrate 101. The first buffer layer 102 is formed of, for example, GaAs or InP. The insulating layer 103 is formed of, for example, SiO₂. The insulating layer 103 can also be formed of an insulating material such as SiN, SiOₓ, or SiON.

The second buffer layer 104 is formed by being regrown through an opening portion 103a from the surface of the substrate 101 which is exposed through the opening portion 103a. The second buffer layer 104 is formed of the same semiconductor (first semiconductor) as the first buffer layer 102. The oxide layer 105 is formed of an oxide of a semiconductor. This semiconductor is a semiconductor on which crystal growth of the semiconductor layer 106 can be performed. The semiconductor layer 106 is formed of a second semiconductor. The semiconductor layer 106 is used to form an optical device.

Here, it is desirable to form the first buffer layer 102 and the second buffer layer 104 of the same semiconductor as the semiconductor layer 106. In addition, it is desirable to form the oxide layer 105 of an oxide of a semiconductor having a lattice constant in a plane direction which is substantially equal to that of the semiconductor layer 106. The oxide layer 105 can be formed of, for example, an oxide of a selectively oxidizable semiconductor containing, for example, Al or the like.

In addition, a total thickness T of the second buffer layer 104 and the oxide layer 105 is larger than a value obtained by multiplying a width W of an opening portion 103a by \sqrt{2}.

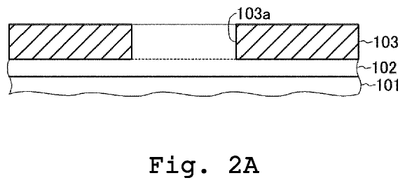

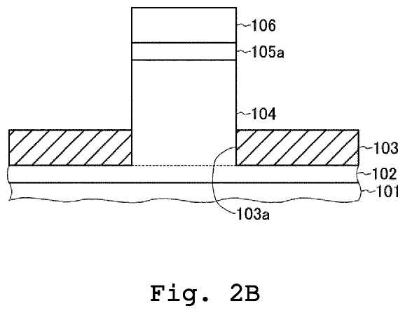

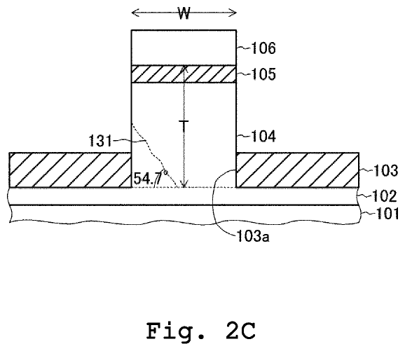

Next, the manufacture of the semiconductor laminated structure according to an embodiment will be described with reference to FIGS. 2A to 2C.

First, as illustrated in FIG. 2A, the first buffer layer 102 is formed on the substrate 101. For example, the first buffer layer 102 can be formed by depositing (growing) GaAs on the substrate 101 by a well-known organic metal vapor phase growth method. The growth of GaAs can also be performed by a molecular beam epitaxy method. Subsequently, the insulating layer 103 is formed by depositing SiO₂ on the first buffer layer 102 by, for example, a sputtering method, a CVD method, or the like. Next, the opening portion 103a penetrating the insulating layer 103 is formed by patterning the insulating layer 103 by a known lithography technique and etching technique.

Next, as illustrated in FIG. 2B, first, the second buffer layer 104 is formed by performing crystal regrowth of GaAs from the surface of the first buffer layer 102 which is exposed through the opening portion 103a by using the insulating layer 103 as a selective growth mask. The second buffer layer 104 is formed to have the same shape as the opening portion 103a when seen in a plan view. Subsequently, an oxide-layer-forming layer 105a is formed by performing crystal growth of AlGaAs on the second buffer layer 104. As described above, the oxide-layer-forming layer 105a is formed of a semiconductor on which crystal growth of the semiconductor layer 106 can be performed. Subsequently, the semiconductor layer 106 is formed by performing crystal growth of GaAs on the oxide-layer-forming layer 105a. The second buffer layer 104, the oxide-layer-forming layer 105a, and the semiconductor layer 106 are formed in a mesa having the same shape as the opening portion 103a when seen in a plan view. Crystal growth of the second buffer layer 104, the oxide-layer-forming layer 105a, and the semiconductor layer 106 can be performed by, for example, an organic metal vapor phase growth method or a molecular beam epitaxy method.

Next, the oxide-layer-forming layer 105a is oxidized (selectively oxidized) from the lateral surface thereof by, for example, a known vapor oxidation method or the like, and the oxide layer 105 is formed on the second buffer layer 104 as illustrated in FIG. 2C, which leads to a state where the semiconductor layer 106 is formed on the oxide layer 105. The oxide layer 105 is formed of Al(Ga)Ox. According to NPL 5, AlGaAs having an Al composition of 80% or more can be oxidized as described above. Thus, in a case where the oxide-layer-forming layer 105a is formed of AlGaAs, it is preferable that an Al composition be 80% or more.

Hereinafter, description will be given in more detail. In the semiconductor laminated structure according to an embodiment, it is considered that a large number of dislocations occur at an interface between the substrate 101 formed of Si and the first buffer layer 102 formed of GaAs due to a difference in a lattice constant in a plane direction (lattice mismatch) therebetween. In a GaAs layer having a plane orientation of (100) of a main surface which is formed (grown) on a substrate of single crystal Si having a plane orientation of 100 of a main surface, it is generally known that a dislocation having a (111) plane as a sliding surface is likely to occur. For this reason, as illustrated in FIG. 2C, a dislocation 131 occurring at an interface (GaAs/Si interface) between the substrate 101 and the first buffer layer 102 propagates to an upper layer at an angle of 54.7 degrees (aspect ratio of \sqrt{2}:1) from the interface.

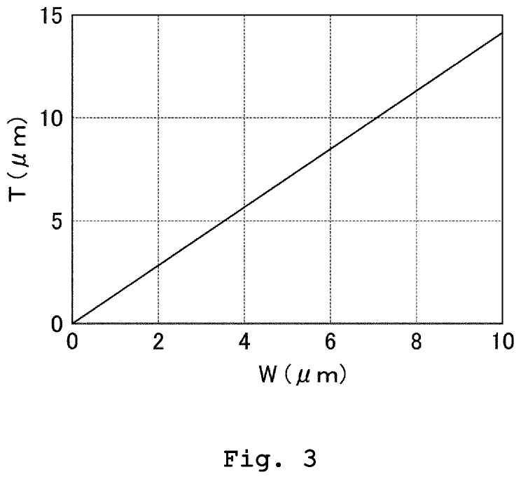

As described above, when the width of the opening portion 103a is W and a thickness from the bottom of the opening portion 103a to the top of the oxide layer 105, in other words, a total thickness of the second buffer layer 104 and the oxide layer 105, is T, it is important that “T>W×\sqrt{2}” be satisfied in order to reduce a dislocation density in the semiconductor layer 106. This relationship is shown as a plot in FIG. 3.

As described above, according to embodiments of the present invention, a total thickness of a second buffer layer and an oxide layer formed from an opening portion of an insulating layer is made larger than a value obtained by multiplying the width of the opening portion by V, and thus it is possible to simply manufacture a semiconductor layer with a significantly reduced dislocation density and to suppress ascending movement of dislocation after the manufacture.

According to embodiments of the present invention, when a semiconductor laminated structure is formed, a semiconductor forming method, an insulating film forming method, a lithography technique, an etching technique, and an oxidation technique, which are generally used, may be preferably used, and particular manufacturing techniques and procedures are not required. A reduction in a dislocation density can be realized only by designing a simple structure specified by the expression “T>W×\sqrt{2}”.

In addition, an amorphous oxide layer is formed below a semiconductor layer for forming an optical device. Thus, even when ascending movement of a dislocation occurs from an interface between a substrate and a first buffer layer during the operation of the device, it is possible to suppress propagation of the dislocation to the semiconductor layer.

Incidentally, in the above-described embodiment, a structure in which lattice mismatch occurs only between the substrate formed of Si and the first buffer layer formed of GaAs is formed, and the first buffer layer, the second buffer layer, the oxide-layer-forming layer which is an oxide layer, and the semiconductor layer are formed of semiconductors having substantially the same lattice constant. As long as the same relationship is satisfied, for example, the following combinations can be used for the substrate/the buffer layer (the first buffer layer, the second buffer layer)/the oxide-layer-forming layer/the semiconductor layer: Si/GaAs/AlAs/GaAs, Si/GaAs/AlGaAs/InGaP, Si/InP/AlAsSb/InP, Si/InP/AlAsSb/InGaAsP, Si/InP/AlAsSb/InGaAlAs, Si/InP/AlSb/InGaAs.

Meanwhile, a combination of the substrate/the buffer layer (the first buffer layer, the second buffer layer)/the oxide-layer-forming layer/the semiconductor layer is not limited to the above-described combinations. Further, in the above-described embodiments, each of the first buffer layer, the second buffer layer, the oxide-layer-forming layer which is an oxide layer, and the semiconductor layer is formed as a single layer. However, this is not limiting, and each of the layers can also be formed using a plurality of materials.

Meanwhile, embodiments of the present invention are not limited to the above-described embodiments, and it is apparent that various modifications and combinations can be made by those skilled in the art without departing from the spirit and scope of the invention.

### REFERENCE SIGNS LIST

101 Substrate
102 First buffer layer
103 Insulating layer
103a Opening portion
104 Second buffer layer
105 Oxide layer
106 Semiconductor layer

1.-5. (canceled)

6. A semiconductor laminated structure, the structure comprising:
a first buffer layer on a substrate, the first buffer layer comprising a first semiconductor having a different lattice constant in a plane direction from a lattice constant of the substrate;
an insulating layer on the first buffer layer, the insulating layer including an opening portion therein;
a second buffer layer in and above the opening portion, the second buffer layer extending upward from a surface of the first buffer layer that is exposed through the opening portion;
an oxide layer on the second buffer layer and comprising an oxide of a semiconductor, wherein a total thickness of the second buffer layer and the oxide layer is larger than a value obtained by multiplying a width of the opening portion by the square root of two (\sqrt{2}); and
a semiconductor layer on the oxide layer, the semiconductor layer comprising a second semiconductor.

7. The structure according to claim 6, wherein the oxide layer comprises the oxide of the semiconductor on which crystal growth of the semiconductor layer is able to be performed.

8. The structure according to claim 6, wherein the substrate comprises Si.

9. The structure according to claim 6, wherein the first buffer layer and the second buffer layer comprise GaAs or InP.

10. The structure according to claim 6, wherein the oxide layer comprises AlAs, AlGaAs, AlAsSb, or an oxide of a compound semiconductor thereof.

11. A method of forming a semiconductor laminated structure, the method comprising:
forming a first buffer layer on a substrate, the first buffer layer comprising a first semiconductor having a different lattice constant in a plane direction from a lattice constant of the substrate;
forming an insulating layer on the first buffer layer;
forming an opening portion in the insulating layer and exposing a surface of the first buffer layer;
forming a second buffer layer in and above the opening portion, the second buffer layer extending upward from the exposed surface of the first buffer layer;
forming an oxide layer on the second buffer layer, the oxide layer comprising an oxide of a semiconductor, wherein a total thickness of the second buffer layer and the oxide layer is larger than a value obtained by multiplying a width of the opening portion by the square root of two (2^{1/2}); and
forming a semiconductor layer on the oxide layer, the semiconductor layer comprising a second semiconductor.

12. The method according to claim 11, wherein the oxide layer comprises the oxide of the semiconductor on which crystal growth of the semiconductor layer is able to be performed.

13. The method according to claim 11, wherein the substrate comprises Si.

14. The method according to claim 11, wherein the first buffer layer and the second buffer layer comprise GaAs or InP.

15. The method according to claim 11, wherein the oxide layer comprises AlAs, AlGaAs, AlAsSb, or an oxide of a compound semiconductor thereof.

16. The method according to claim 11, wherein forming the first buffer layer on the substrate comprises growing GaAs on the substrate comprising Si.

17. The method according to claim 16, wherein forming the insulating layer comprises depositing SiO₂ on the first buffer layer.

18. The method according to claim 17, wherein forming the opening portion in the insulating layer comprises patterning the insulating layer using a lithography technique and an etching technique.

19. The method according to claim 16, wherein forming the second buffer layer comprises performing crystal regrowth of the GaAs from the exposed surface of the first buffer layer using the insulating layer as a selective growth mask.

20. The method according to claim 11, wherein the second buffer layer, the oxide layer, and the semiconductor layer are formed in a mesa having a same shape as the opening portion when viewed in a plan view.
